(19) United States
(12) Patent Application Publication
(10) Pub. No.: US 2024/0234408 A1
(43) Pub. Date: Jul. 11, 2024

(54) ELECTROSTATIC DISCHARGE (ESD) PROTECTION DEVICE

(71) Applicant: AMAZING MICROELECTRONIC CORP., New Taipei City (TW)

(72) Inventors: KUN-HSIEN LIN, Hsinchu City (TW); Zi-Ping CHEN, New Taipei City (TW); Tun-Chih Yang, New Taipei City (TW)

(73) Assignee: AMAZING MICROELECTRONIC CORP., New Taipei City (TW)

(21) Appl. No.: 18/095,178

(22) Filed: Jan. 10, 2023

(51) Int. Cl. H01L 27/02

(52) U.S. Cl. CPC H01L 27/0262; H01L 27/0255

(57) ABSTRACT

An ESD protection device includes an N-type semiconductor substrate, a P-type semiconductor layer, a first N-type well, a P-type well, a second N-type well, a first P-type heavily-doped area, a first N-type heavily-doped area, and a second P-type heavily-doped area. The semiconductor layer is formed on the substrate. The wells are formed in the semiconductor layer. The second N-type well directly touches the substrate. The first P-type heavily-doped area is formed in the first N-type well. The first N-type heavily-doped area and the second P-type heavily-doped area are formed in the P-type well. The second P-type heavily-doped area is coupled to the second N-type well through an external conductive wire and replaced with a second N-type heavily-doped area.

### BACKGROUND OF THE INVENTION

### Field of the Invention

The present invention relates to a protection device, particularly to an electrostatic discharge (ESD) protection device.

### Description of the Related Art

Electrostatic Discharge (ESD) damage has become the main reliability issue for CMOS IC products fabricated in the nanoscale CMOS processes. ESD protection device is generally designed to bypass the ESD energy, so that the IC chips can be prevented from ESD damages.

The working principle of ESD protection device is shown in FIG. 1. In FIG. 1, the ESD protection device 1 is connected in parallel with a protected circuit 2 on the IC chip. The ESD protection device 1 would be triggered immediately when the ESD event occurs. In that way, the ESD protection device 1 can provide a superiorly low resistance path for discharging the transient ESD current, so that the energy of the ESD transient current can be bypassed by the ESD protection device 1. In the U.S. Pat. No. 10,896,903B2, FIG. 1 shows a semiconductor device including a p−-type anode region and an n-type cathode region. When an ESD current flows from the cathode to the anode, the p−-type anode region and the n-type cathode region have a high breakdown voltage. Thus, the semiconductor device cannot be used for low-voltage applications. When an ESD current flows from the anode to the cathode, the semiconductor device has a high clamping voltage due to the low doping concentration of the p−-type anode region and the n-type cathode region. In the U.S. Pat. No. 10,923,466B2, an ESD current flows through a parasitic NPN BJT when the first pin and the second pin are respectively coupled to a high voltage and a low voltage. Due to the high holding voltage of the NPN BJT, the turned-on BJT has a high clamping voltage.

To overcome the abovementioned problems, the present invention provides an electrostatic discharge (ESD) protection device, so as to solve the afore-mentioned problems of the prior art.

### SUMMARY OF THE INVENTION

The present invention provides an electrostatic discharge (ESD) protection device, which has a low triggered-on voltage and a low clamping voltage. The ESD protection device is used for low-voltage applications.

The present invention provides an electrostatic discharge (ESD) protection device, which includes an N-type semiconductor substrate, a P-type semiconductor layer, a first N-type well, a P-type well, a second N-type well, a first P-type heavily-doped area, a first N-type heavily-doped area and a second P-type heavily-doped area. The P-type semiconductor layer is formed on the N-type semiconductor substrate. The first N-type well, the P-type well, and the second N-type well are formed in the P-type semiconductor layer. The second N-type well directly touches the N-type semiconductor substrate. The first P-type heavily-doped area is formed in the first N-type well. The first N-type heavily-doped area and the second P-type heavily-doped area are formed in the P-type well. The second P-type heavily-doped area is coupled to the second N-type well through an external conductive wire.

In an embodiment of the present invention, the second N-type well is an N-type heavily-doped well.

In an embodiment of the present invention, the ESD protection device further includes an N-type heavily-doped area formed in the second N-type well.

In an embodiment of the present invention, the ESD protection device further includes a second N-type heavily-doped area formed in the first N-type well.

In an embodiment of the present invention, the first N-type heavily-doped area, the first P-type heavily-doped area, and the second N-type heavily-doped area are coupled to a first pin and the N-type semiconductor substrate is coupled to a second pin.

In an embodiment of the present invention, the first P-type heavily-doped area, the first N-type well, the P-type semiconductor layer, and the N-type semiconductor substrate form a parasitic silicon-controlled rectifier (SCR), and the first N-type heavily-doped area, the P-type well, the P-type semiconductor layer, and the N-type semiconductor substrate form a parasitic bipolar junction transistor (BJT). When the first pin and the second pin respectively receive a positive electrostatic discharge (ESD) voltage and a grounding voltage, an electrostatic discharge (ESD) current flows from the first pin to the second pin through the parasitic SCR and the parasitic BJT.

In an embodiment of the present invention, the P-type well, the first N-type heavily-doped area, and the second P-type heavily-doped area form a parasitic diode. When the first pin and the second pin respectively receive a negative electrostatic discharge (ESD) voltage and a grounding voltage, an electrostatic discharge (ESD) current flows from the second pin to the first pin through the N-type semiconductor substrate, the second N-type well, the external conductive wire, and the parasitic diode. In an embodiment of the present invention, the first N-type heavily-doped area, the first P-type heavily-doped area, and the second N-type heavily-doped area are coupled to a first pin and the external conductive wire is coupled to a second pin.

In an embodiment of the present invention, the first P-type heavily-doped area, the first N-type well, the P-type semiconductor layer, the N-type semiconductor substrate, and the second N-type well form a parasitic silicon-controlled rectifier (SCR). The first N-type heavily-doped area, the P-type well, the P-type semiconductor layer, the N-type semiconductor substrate, and the second N-type well form a parasitic bipolar junction transistor (BJT). When the first pin and the second pin respectively receive a positive electrostatic discharge (ESD) voltage and a grounding voltage, an electrostatic discharge (ESD) current flows from the first pin to the second pin through the parasitic SCR and the parasitic BJT.

In an embodiment of the present invention, the P-type well, the first N-type heavily-doped area, and the second P-type heavily-doped area form a parasitic diode. When the first pin and the second pin respectively receive a negative electrostatic discharge (ESD) voltage and a grounding voltage, an electrostatic discharge (ESD) current flows from the second pin to the first pin through the external conductive wire and the parasitic diode.

In an embodiment of the present invention, the ESD protection device further includes a third P-type heavily-doped area formed in the P-type well. The third P-type heavily-doped area directly touches the bottom of the first N-type heavily-doped area.

In an embodiment of the present invention, an electrostatic discharge (ESD) protection device includes an N-type semiconductor substrate, a P-type semiconductor layer, a first N-type well, a P-type well, a second N-type well, a first P-type heavily-doped area, a first N-type heavily-doped area, and a second N-type heavily-doped area. The P-type semiconductor layer is formed on the N-type semiconductor substrate. The first N-type well, the P-type well, and the second N-type well are formed in the P-type semiconductor layer. The second N-type well directly touches the N-type semiconductor substrate. The first P-type heavily-doped area is formed in the first N-type well. The first N-type heavily-doped area and the second N-type heavily-doped area are formed in the P-type well. The second N-type heavily-doped area is coupled to the second N-type well through an external conductive wire.

In an embodiment of the present invention, the second N-type well is an N-type heavily-doped well.

In an embodiment of the present invention, the ESD protection device further includes an N-type heavily-doped area formed in the second N-type well.

In an embodiment of the present invention, the ESD protection device further includes a third N-type heavily-doped area formed in the first N-type well.

In an embodiment of the present invention, the first N-type heavily-doped area, the first P-type heavily-doped area, and the third N-type heavily-doped area are coupled to a first pin and the N-type semiconductor substrate is coupled to a second pin.

In an embodiment of the present invention, the first P-type heavily-doped area, the first N-type well, the P-type semiconductor layer, and the N-type semiconductor substrate form a parasitic silicon-controlled rectifier (SCR), and the first N-type heavily-doped area, the P-type well, the P-type semiconductor layer, and the N-type semiconductor substrate form a parasitic vertical bipolar junction transistor (BJT). When the first pin and the second pin respectively receive a positive electrostatic discharge (ESD) voltage and a grounding voltage, an electrostatic discharge (ESD) current flows from the first pin to the second pin through the parasitic SCR and the parasitic vertical BJT.

In an embodiment of the present invention, the P-type well, the first N-type heavily-doped area, and the second N-type heavily-doped area form a parasitic lateral bipolar junction transistor (BJT). When the first pin and the second pin respectively receive a negative electrostatic discharge (ESD) voltage and a grounding voltage, an electrostatic discharge (ESD) current flows from the second pin to the first pin through the N-type semiconductor substrate, the second N-type well, the external conductive wire, and the parasitic lateral BJT.

In an embodiment of the present invention, the first N-type heavily-doped area, the first P-type heavily-doped area, and the third N-type heavily-doped area are coupled to a first pin and the external conductive wire is coupled to a second pin.

In an embodiment of the present invention, the first P-type heavily-doped area, the first N-type well, the P-type semiconductor layer, the N-type semiconductor substrate, and the second N-type well form a parasitic silicon-controlled rectifier (SCR). The first N-type heavily-doped area, the P-type well, the P-type semiconductor layer, the N-type semiconductor substrate, and the second N-type well form a parasitic vertical bipolar junction transistor (BJT). When the first pin and the second pin respectively receive a positive electrostatic discharge (ESD) voltage and a grounding voltage, an electrostatic discharge (ESD) current flows from the first pin to the second pin through the parasitic SCR and the parasitic vertical BJT.

In an embodiment of the present invention, the P-type well, the first N-type heavily-doped area, and the second N-type heavily-doped area form a parasitic lateral bipolar junction transistor (BJT). When the first pin and the second pin respectively receive a negative electrostatic discharge (ESD) voltage and a grounding voltage, an electrostatic discharge (ESD) current flows from the second pin to the first pin through the external conductive wire and the parasitic lateral BJT.

In an embodiment of the present invention, the ESD protection device further includes a second P-type heavily-doped area formed in the P-type well. The second P-type heavily-doped area directly touches a bottom of the first N-type heavily-doped area.

In an embodiment of the present invention, the ESD protection device further includes a third P-type heavily-doped area formed in the P-type well. The third P-type heavily-doped area directly touches a bottom of the second N-type heavily-doped area.

To sum up, the ESD protection device employs a parasitic BJT to help turn on a parasitic SCR, thereby decreasing a trigger-on voltage and a clamping voltage. The ESD protection device also forms a lateral diode or BJT to decrease a clamping voltage. Thus, the ESD protection device is used for low-voltage applications.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating an electrostatic discharge (ESD) protection device connected with a protected circuit on an IC chip in the conventional technology;

FIG. 2 is a cross-sectional view of an ESD protection device according to a first embodiment of the present invention;

FIG. 3 is a cross-sectional view of an ESD protection device according to a second embodiment of the present invention;

FIG. 4 is a cross-sectional view of an ESD protection device according to a third embodiment of the present invention;

FIG. 5 is a cross-sectional view of an ESD protection device according to a fourth embodiment of the present invention;

FIG. 6 is a cross-sectional view of an ESD protection device according to a fifth embodiment of the present invention;

FIG. 7 is a cross-sectional view of an ESD protection device according to a sixth embodiment of the present invention;

FIG. 8 is a cross-sectional view of an ESD protection device according to a seventh embodiment of the present invention; and

FIG. 9 is a cross-sectional view of an ESD protection device according to an eighth embodiment of the present invention.

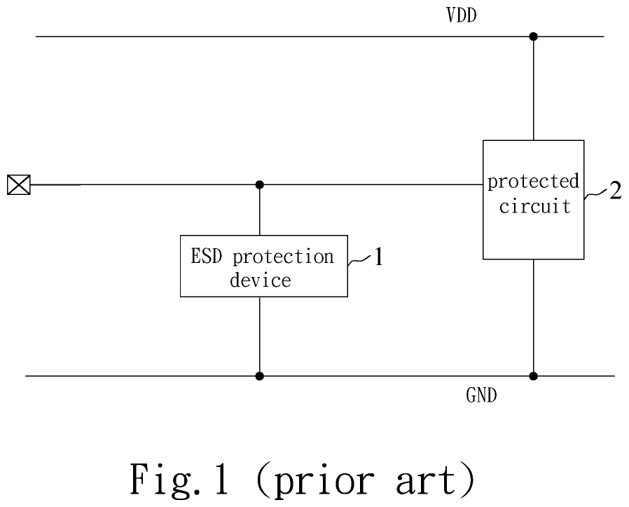

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled with,” “couples with,” and “coupling with” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means. When a component is referred to as being “directly on,” “directly connected to,” “directly coupled to,” or “directly engaged with” another component, there are no intervening components present.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, an electrostatic discharge (ESD) protection device will be described. The ESD protection device employs a parasitic BJT to help turn on a parasitic SCR, thereby decreasing a trigger-on voltage and a clamping voltage. The ESD protection device also forms a lateral diode or BJT to decrease a clamping voltage. Thus, the ESD protection device is used for low-voltage applications.

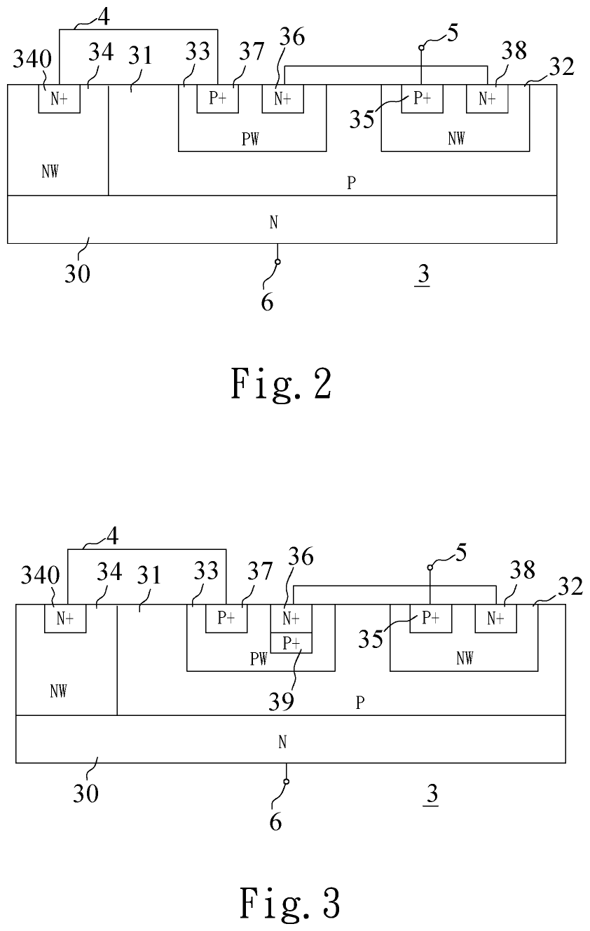

FIG. 2 is a cross-sectional view of an ESD protection device according to a first embodiment of the present invention. Referring to FIG. 2, the first embodiment of the ESD protection device 3 is introduced as follows. The first embodiment is a uni-directional ESD protection device. The ESD protection device 3 includes an N-type semiconductor substrate 30, a P-type semiconductor layer 31, a first N-type well 32, a P-type well 33, a second N-type well 34, a first P-type heavily-doped area 35, a first N-type heavily-doped area 36, and a second P-type heavily-doped area 37. The P-type semiconductor layer 31 is formed on the N-type semiconductor substrate 30. The first N-type well 32, the P-type well 33, and the second N-type well 34 are formed in the P-type semiconductor layer 31. The second N-type well 34 directly touches the N-type semiconductor substrate 30. There is nothing between the second N-type well 34 and the N-type semiconductor substrate 30. The ESD protection device 3 may further include an N-type heavily-doped area 340 formed in the second N-type well 34 to form an ohmic contact. Alternatively, the second N-type well 34 may be an N-type heavily-doped well to form an ohmic contact. The first P-type heavily-doped area 35 is formed in the first N-type well 32. The first N-type heavily-doped area 36 and the second P-type heavily-doped area 37 are formed in the P-type well 33. The second P-type heavily-doped area 37 is coupled to the N-type heavily-doped 340 or the second N-type well 34 through an external conductive wire 4. In some embodiments, the P-type well 33 may be formed between the first N-type well 32 and the second N-type well 34. In order to form the ohmic contact of the first N-type well 32, the ESD protection device 3 may further include a second N-type heavily-doped area 38 formed in the first N-type well 32. The first N-type heavily-doped area 36, the first P-type heavily-doped area 35, and the second N-type heavily-doped area 38 are coupled to a first pin 5 and the N-type semiconductor substrate 30 is coupled to a second pin 6.

The first P-type heavily-doped area 35, the first N-type well 32, the P-type semiconductor layer 31, and the N-type semiconductor substrate 30 form a parasitic silicon-controlled rectifier (SCR). The first N-type heavily-doped area 36, the P-type well 33, the P-type semiconductor layer 31, and the N-type semiconductor substrate 30 form a parasitic bipolar junction transistor (BJT). The parasitic SCR and the parasitic BJT have to share the same P-type semiconductor layer 31. An electrostatic discharge (ESD) current flows from the first pin 5 to the second pin 6 through the parasitic SCR and the parasitic BJT when the first pin 5 and the second pin 6 respectively receive a positive electrostatic discharge (ESD) voltage and a grounding voltage. The voltage potential of the P-type semiconductor layer 31 is increased due to the breakdown event of a junction between the first N-type heavily-doped area 36 and the P-type well 33. Thus, a forward bias is generated across the P-type semiconductor layer 31 and the N-type semiconductor substrate 30. The parasitic BJT can help turn on the parasitic SCR, thereby decreasing a trigger-on voltage and a clamping voltage. It is noted that the trigger-on voltage of the ESD protection device 3 depends on the trigger-on voltage of the parasitic BJT since the trigger-on voltage of the parasitic BJT is lower than the trigger-on voltage of the parasitic SCR. As a result, the ESD protection device 3 is used for low-voltage applications.

The P-type well 33, the first N-type heavily-doped area 36, and the second P-type heavily-doped area 37 form a lateral parasitic diode. When the first pin 5 and the second pin 6 respectively receive a negative ESD voltage and a grounding voltage, an electrostatic discharge (ESD) current flows from the second pin 6 to the first pin 5 through the N-type semiconductor substrate 30, the second N-type well 34, the N-type heavily-doped 340, the external conductive wire 4, and the parasitic diode. The path of the parasitic diode has a low clamping voltage.

FIG. 3 is a cross-sectional view of an ESD protection device according to a second embodiment of the present invention. Referring to FIG. 3, the second embodiment of the ESD protection device 3 is introduced as follows. The second embodiment is different from the first embodiment in that the second embodiment of the ESD protection device 3 further includes a third P-type heavily-doped area 39 formed in the P-type well 33. The third P-type heavily-doped area 39 directly touches the bottom of the first N-type heavily-doped area 36. There is nothing between the third P-type heavily-doped area 39 and the bottom of the first N-type heavily-doped area 36. The other features have been described previously in the first embodiment so it will not be reiterated. The voltage potential of the P-type semiconductor layer 31 is increased due to the breakdown event of a junction between the first N-type heavily-doped area 36 and the third P-type heavily-doped area 39. The third P-type heavily-doped area 39 can further decrease the trigger-on voltage of the parasitic BJT. Thus, a forward bias is generated across the P-type semiconductor layer 31 and the N-type semiconductor substrate 30. The parasitic BJT can help turn on the parasitic SCR, thereby decreasing a trigger-on voltage and a clamping voltage. It is noted that the trigger-on voltage of the ESD protection device 3 depends on the trigger-on voltage of the parasitic BJT since the trigger-on voltage of the parasitic BJT is lower than the trigger-on voltage of the parasitic SCR.

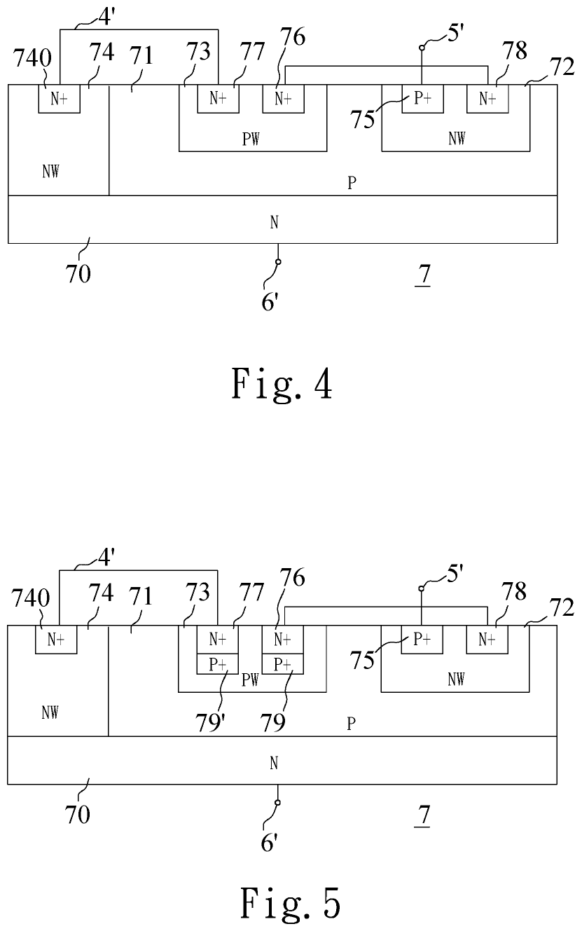

FIG. 4 is a cross-sectional view of an ESD protection device according to a third embodiment of the present invention. Referring to FIG. 4, the third embodiment of the ESD protection device 7 is introduced as follows. The third embodiment is a bi-directional ESD protection device. The ESD protection device 7 includes an N-type semiconductor substrate 70, a P-type semiconductor layer 71, a first N-type well 72, a P-type well 73, a second N-type well 74, a first P-type heavily-doped area 75, a first N-type heavily-doped area 76, and a second N-type heavily-doped area 77. The P-type semiconductor layer 71 is formed on the N-type semiconductor substrate 70. The first N-type well 72, the P-type well 73, and the second N-type well 74 are formed in the P-type semiconductor layer 71. The second N-type well 74 directly touches the N-type semiconductor substrate 70. There is nothing between the second N-type well 74 and the N-type semiconductor substrate 70. The ESD protection device 7 may further include an N-type heavily-doped area 740 formed in the second N-type well 74 to form an ohmic contact. Alternatively, the second N-type well 74 may be an N-type heavily-doped well to form an ohmic contact. The first P-type heavily-doped area 75 is formed in the first N-type well 72. The first N-type heavily-doped area 76 and the second N-type heavily-doped area 77 are formed in the P-type well 73. The second N-type heavily-doped area 77 is coupled to the second N-type well 74 through an external conductive wire 4′. In some embodiments, the P-type well 73 may be formed between the first N-type well 72 and the second N-type well 74. In order to form the ohmic contact of the first N-type well 72, the ESD protection device 7 may further include a third N-type heavily-doped area 78 formed in the first N-type well 72. The first N-type heavily-doped area 76, the first P-type heavily-doped area 75, and the third N-type heavily-doped area 78 are coupled to a first pin 5′ and the N-type semiconductor substrate 70 is coupled to a second pin 6′.

The first P-type heavily-doped area 75, the first N-type well 72, the P-type semiconductor layer 71, and the N-type semiconductor substrate 70 form a parasitic silicon-controlled rectifier (SCR). The first N-type heavily-doped area 76, the P-type well 73, the P-type semiconductor layer 71, and the N-type semiconductor substrate 70 form a parasitic vertical bipolar junction transistor (BJT). The parasitic SCR and the parasitic vertical BJT have to share the same P-type semiconductor layer 71. An electrostatic discharge (ESD) current flows from the first pin 5′ to the second pin 6′ through the parasitic SCR and the parasitic vertical BJT when the first pin 5′ and the second pin 6′ respectively receive a positive ESD voltage and a grounding voltage. The voltage potential of the P-type semiconductor layer 71 is increased due to the breakdown event of a junction between the first N-type heavily-doped area 76 and the P-type well 73. Thus, a forward bias is generated across the P-type semiconductor layer 71 and the N-type semiconductor substrate 70. The parasitic vertical BJT can help turn on the parasitic SCR, thereby decreasing a trigger-on voltage and a clamping voltage. It is noted that the trigger-on voltage of the ESD protection device 7 depends on the trigger-on voltage of the parasitic vertical BJT since the trigger-on voltage of the parasitic vertical BJT is lower than the trigger-on voltage of the parasitic SCR. As a result, the ESD protection device 7 is used for low-voltage applications.

The P-type well 73, the first N-type heavily-doped area 76, and the second N-type heavily-doped area 77 form a parasitic lateral bipolar junction transistor (BJT). When the first pin 5′ and the second pin 6′ respectively receive a negative ESD voltage and a grounding voltage, an electrostatic discharge (ESD) current flows from the second pin 6′ to the first pin 5′ through the N-type semiconductor substrate 70, the second N-type well 74, the N-type heavily-doped 740, the external conductive wire 4′, and the parasitic lateral BJT. The path of the parasitic lateral BJT has a low clamping voltage.

FIG. 5 is a cross-sectional view of an ESD protection device according to a fourth embodiment of the present invention. Referring to FIG. 5, the fourth embodiment of the ESD protection device 7 is introduced as follows. The fourth embodiment is different from the third embodiment in that the fourth embodiment of the ESD protection device 7 further includes a second P-type heavily-doped area 79 formed in the P-type well 73. The second P-type heavily-doped area 79 directly touches the bottom of the first N-type heavily-doped area 76. There is nothing between the second P-type heavily-doped area 79 and the bottom of the first N-type heavily-doped area 76. The other features have been described previously in the third embodiment so it will not be reiterated. The voltage potential of the P-type semiconductor layer 71 is increased due to the breakdown event of a junction between the first N-type heavily-doped area 76 and the second P-type heavily-doped area 79. The second P-type heavily-doped area 79 can further decrease the trigger-on voltage of the parasitic vertical BJT. Thus, a forward bias is generated across the P-type semiconductor layer 71 and the N-type semiconductor substrate 70. The parasitic vertical BJT can help turn on the parasitic SCR, thereby decreasing a trigger-on voltage and a clamping voltage. It is noted that the trigger-on voltage of the ESD protection device 7 depends on the trigger-on voltage of the parasitic BJT since the trigger-on voltage of the parasitic vertical BJT is lower than the trigger-on voltage of the parasitic SCR.

In addition, the ESD protection device 7 may further include a third P-type heavily-doped area 79′ formed in the P-type well 73. The third P-type heavily-doped area 79′ directly touches the bottom of the second N-type heavily-doped area 77. There is nothing between the third P-type heavily-doped area 79′ and the bottom of the second N-type heavily-doped area 77. The third P-type heavily-doped area 79′ can further decrease the trigger-on voltage and the clamping voltage of the parasitic lateral BJT.

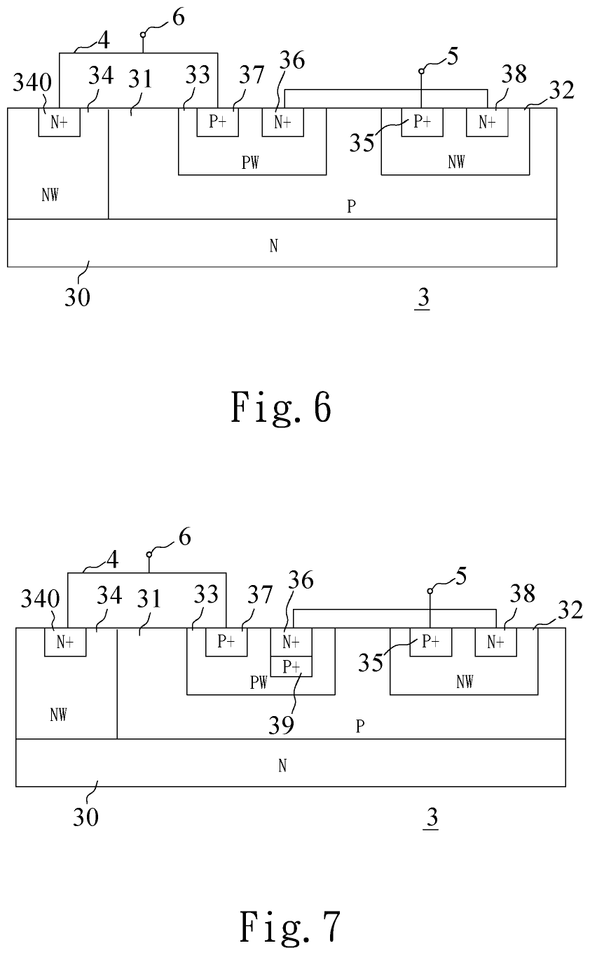

FIG. 6 is a cross-sectional view of an ESD protection device according to a fifth embodiment of the present invention. Referring to FIG. 6, the fifth embodiment of the ESD protection device 3 is introduced as follows. The fifth embodiment is different from the first embodiment in the location of the second pin 6. In the fifth embodiment, the second pin 6 is coupled to the external conductive wire 4. The other features have been described previously so it will not be reiterated.

The first P-type heavily-doped area 35, the first N-type well 32, the P-type semiconductor layer 31, the N-type semiconductor substrate 30, the second N-type well 34, and the N-type heavily-doped area 340 form a parasitic silicon-controlled rectifier (SCR). The first N-type heavily-doped area 36, the P-type well 33, the P-type semiconductor layer 31, the N-type semiconductor substrate 30, the second N-type well 34, and the N-type heavily-doped area 340 form a parasitic bipolar junction transistor (BJT). When the first pin 5 and the second pin 6 respectively receive a positive electrostatic discharge (ESD) voltage and a grounding voltage, an electrostatic discharge (ESD) current flows from the first pin 5 to the second pin 6 through the parasitic SCR and the parasitic BJT. The voltage potential of the P-type semiconductor layer 31 is increased due to the breakdown event of a junction between the first N-type heavily-doped area 36 and the P-type well 33. Thus, a forward bias is generated across the P-type semiconductor layer 31 and the N-type semiconductor substrate 30. The parasitic BJT can help turn on the parasitic SCR, thereby decreasing a trigger-on voltage and a clamping voltage. It is noted that the trigger-on voltage of the ESD protection device 3 depends on the trigger-on voltage of the parasitic BJT since the trigger-on voltage of the parasitic BJT is lower than the trigger-on voltage of the parasitic SCR. As a result, the ESD protection device 3 is used for low-voltage applications.

The P-type well 33, the first N-type heavily-doped area 36, and the second P-type heavily-doped area 37 form a lateral parasitic diode. When the first pin 5 and the second pin 6 respectively receive a negative electrostatic discharge (ESD) voltage and a grounding voltage, an electrostatic discharge (ESD) current flows from the second pin 6 to the first pin 5 through the external conductive wire 4 and the parasitic diode. The path of the parasitic diode has a low clamping voltage.

FIG. 7 is a cross-sectional view of an ESD protection device according to a sixth embodiment of the present invention. The sixth embodiment of the ESD protection device 3 is introduced as follows. The sixth embodiment is different from the fifth embodiment in that the sixth embodiment of the ESD protection device 3 further includes a third P-type heavily-doped area 39 formed in the P-type well 33. The third P-type heavily-doped area 39 directly touches the bottom of the first N-type heavily-doped area 36. There is nothing between the third P-type heavily-doped area 39 and the bottom of the first N-type heavily-doped area 36. The other features have been described previously in the fifth embodiment so will not be reiterated. The voltage potential of the P-type semiconductor layer 31 is increased due to the breakdown event of a junction between the first N-type heavily-doped area 36 and the third P-type heavily-doped area 39. The third P-type heavily-doped area 39 can further decrease the trigger-on voltage of the parasitic BJT. Thus, a forward bias is generated across the P-type semiconductor layer 31 and the N-type semiconductor substrate 30. The parasitic BJT can help turn on the parasitic SCR, thereby decreasing a trigger-on voltage and a clamping voltage. It is noted that the trigger-on voltage of the ESD protection device 3 depends on the trigger-on voltage of the parasitic BJT since the trigger-on voltage of the parasitic BJT is lower than the trigger-on voltage of the parasitic SCR.

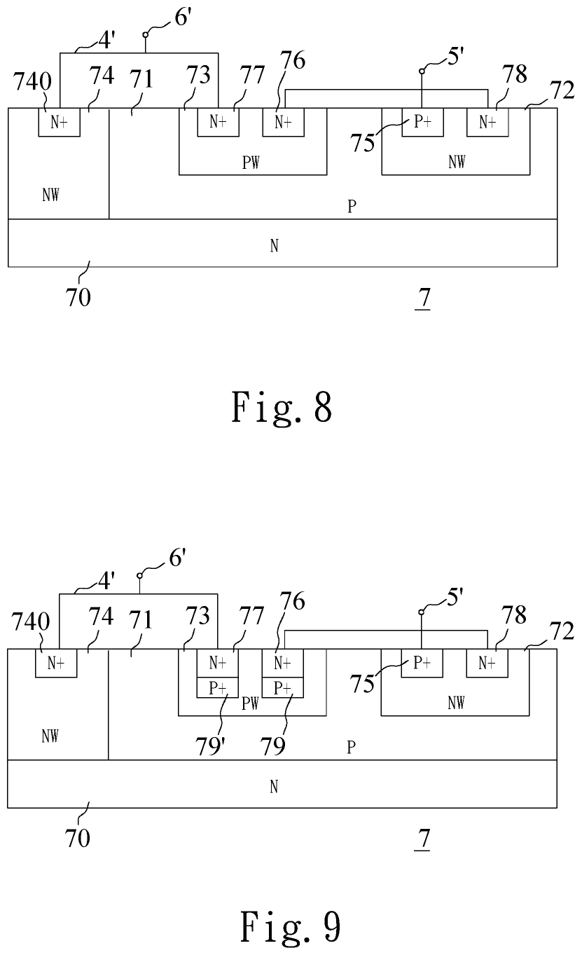

FIG. 8 is a cross-sectional view of an ESD protection device according to a seventh embodiment of the present invention. Referring to FIG. 8, the seventh embodiment of the ESD protection device 7 is introduced as follows. The seventh embodiment is different from the third embodiment in the location of the second pin 6′. In the seventh embodiment, the second pin 6′ is coupled to the external conductive wire 4′.

The first P-type heavily-doped area 75, the first N-type well 72, the P-type semiconductor layer 71, the N-type semiconductor substrate 70, the second N-type well 74, and the N-type heavily-doped area 740 form a parasitic silicon-controlled rectifier (SCR). The first N-type heavily-doped area 76, the P-type well 73, the P-type semiconductor layer 71, the N-type semiconductor substrate 70, the second N-type well 74, and the N-type heavily-doped area 740 form a parasitic vertical bipolar junction transistor (BJT). When the first pin 5′ and the second pin 6′ respectively receive a positive electrostatic discharge (ESD) voltage and a grounding voltage, an electrostatic discharge (ESD) current flows from the first pin 5′ to the second pin 6′ through the parasitic SCR and the parasitic vertical BJT. The voltage potential of the P-type semiconductor layer 71 is increased due to the breakdown event of a junction between the first N-type heavily-doped area 76 and the P-type well 73. Thus, a forward bias is generated across the P-type semiconductor layer 71 and the N-type semiconductor substrate 70. The parasitic vertical BJT can help turn on the parasitic SCR, thereby decreasing a trigger-on voltage and a clamping voltage. It is noted that the trigger-on voltage of the ESD protection device 7 depends on the trigger-on voltage of the parasitic vertical BJT since the trigger-on voltage of the parasitic vertical BJT is lower than the trigger-on voltage of the parasitic SCR. As a result, the ESD protection device 7 is used for low-voltage applications.

The P-type well 73, the first N-type heavily-doped area 76, and the second N-type heavily-doped area 77 form a parasitic lateral bipolar junction transistor (BJT). When the first pin 5′ and the second pin 6′ respectively receive a negative electrostatic discharge (ESD) voltage and a grounding voltage, an electrostatic discharge (ESD) current flows from the second pin 6′ to the first pin 5′ through the external conductive wire 4′ and the parasitic lateral BJT. The path of the parasitic lateral BJT has a low clamping voltage.

FIG. 9 is a cross-sectional view of an ESD protection device according to an eighth embodiment of the present invention. Referring to FIG. 9, the eighth embodiment of the ESD protection device 7 is introduced as follows. The eighth embodiment is different from the seventh embodiment in that the eighth embodiment of the ESD protection device 7 further includes a second P-type heavily-doped area 79 formed in the P-type well 73. The second P-type heavily-doped area 79 directly touches the bottom of the first N-type heavily-doped area 76. There is nothing between the second P-type heavily-doped area 79 and the bottom of the first N-type heavily-doped area 76. The other features have been described previously in the seventh embodiment so it will not be reiterated. The voltage potential of the P-type semiconductor layer 71 is increased due to the breakdown event of a junction between the first N-type heavily-doped area 76 and the second P-type heavily-doped area 79. The second P-type heavily-doped area 79 can further decrease the trigger-on voltage of the parasitic vertical BJT. Thus, a forward bias is generated across the P-type semiconductor layer 71 and the N-type semiconductor substrate 70. The parasitic vertical BJT can help turn on the parasitic SCR, thereby decreasing a trigger-on voltage and a clamping voltage. It is noted that the trigger-on voltage of the ESD protection device 7 depends on the trigger-on voltage of the parasitic BJT since the trigger-on voltage of the parasitic vertical BJT is lower than the trigger-on voltage of the parasitic SCR.

In addition, the ESD protection device 7 may further include a third P-type heavily-doped area 79′ formed in the P-type well 73. The third P-type heavily-doped area 79′ directly touches the bottom of the second N-type heavily-doped area 77. There is nothing between the third P-type heavily-doped area 79′ and the bottom of the second N-type heavily-doped area 77. The third P-type heavily-doped area 79′ can further decrease the trigger-on voltage and the clamping voltage of the parasitic lateral BJT.

According to the embodiments provided above, the ESD protection device has a low triggered-on voltage and a low clamping voltage. The ESD protection device is used for low-voltage applications.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. An electrostatic discharge (ESD) protection device comprising:
an N-type semiconductor substrate;
a P-type semiconductor layer formed on the N-type semiconductor substrate;
a first N-type well, a P-type well, and a second N-type well formed in the P-type semiconductor layer, wherein the second N-type well directly touches the N-type semiconductor substrate;
a first P-type heavily-doped area formed in the first N-type well; and
a first N-type heavily-doped area and a second P-type heavily-doped area formed in the P-type well, wherein the second P-type heavily-doped area is coupled to the second N-type well through an external conductive wire.

2. The ESD protection device according to claim 1, wherein the second N-type well is an N-type heavily-doped well.

3. The ESD protection device according to claim 1, further comprising an N-type heavily-doped area formed in the second N-type well.

4. The ESD protection device according to claim 1, further comprising a second N-type heavily-doped area formed in the first N-type well.

5. The ESD protection device according to claim 4, wherein the first N-type heavily-doped area, the first P-type heavily-doped area, and the second N-type heavily-doped area are coupled to a first pin and the N-type semiconductor substrate is coupled to a second pin.

6. The ESD protection device according to claim 5, wherein the first P-type heavily-doped area, the first N-type well, the P-type semiconductor layer, and the N-type semiconductor substrate form a parasitic silicon-controlled rectifier (SCR), the first N-type heavily-doped area, the P-type well, the P-type semiconductor layer, and the N-type semiconductor substrate form a parasitic bipolar junction transistor (BJT), and when the first pin and the second pin respectively receive a positive electrostatic discharge (ESD) voltage and a grounding voltage, an electrostatic discharge (ESD) current flows from the first pin to the second pin through the parasitic SCR and the parasitic BJT.

7. The ESD protection device according to claim 5, wherein the P-type well, the first N-type heavily-doped area, and the second P-type heavily-doped area form a parasitic diode, and when the first pin and the second pin respectively receive a negative electrostatic discharge (ESD) voltage and a grounding voltage, an electrostatic discharge (ESD) current flows from the second pin to the first pin through the N-type semiconductor substrate, the second N-type well, the external conductive wire, and the parasitic diode.

8. The ESD protection device according to claim 4, wherein the first N-type heavily-doped area, the first P-type heavily-doped area, and the second N-type heavily-doped area are coupled to a first pin and the external conductive wire is coupled to a second pin.

9. The ESD protection device according to claim 8, wherein the first P-type heavily-doped area, the first N-type well, the P-type semiconductor layer, the N-type semiconductor substrate, and the second N-type well form a parasitic silicon-controlled rectifier (SCR), the first N-type heavily-doped area, the P-type well, the P-type semiconductor layer, the N-type semiconductor substrate, and the second N-type well form a parasitic bipolar junction transistor (BJT), and when the first pin and the second pin respectively receive a positive electrostatic discharge (ESD) voltage and a grounding voltage, an electrostatic discharge (ESD) current flows from the first pin to the second pin through the parasitic SCR and the parasitic BJT.

10. The ESD protection device according to claim 8, wherein the P-type well, the first N-type heavily-doped area, and the second P-type heavily-doped area form a parasitic diode, and when the first pin and the second pin respectively receive a negative electrostatic discharge (ESD) voltage and a grounding voltage, an electrostatic discharge (ESD) current flows from the second pin to the first pin through the external conductive wire and the parasitic diode.

11. The ESD protection device according to claim 1, further comprising a third P-type heavily-doped area formed in the P-type well, and the third P-type heavily-doped area directly touches a bottom of the first N-type heavily-doped area.

12. An electrostatic discharge (ESD) protection device comprising:
an N-type semiconductor substrate;
a P-type semiconductor layer formed on the N-type semiconductor substrate;
a first N-type well, a P-type well, and a second N-type well formed in the P-type semiconductor layer, wherein the second N-type well directly touches the N-type semiconductor substrate;
a first P-type heavily-doped area formed in the first N-type well; and
a first N-type heavily-doped area and a second N-type heavily-doped area formed in the P-type well, wherein the second N-type heavily-doped area is coupled to the second N-type well through an external conductive wire.

13. The ESD protection device according to claim 12, wherein the second N-type well is an N-type heavily-doped well.

14. The ESD protection device according to claim 12, further comprising an N-type heavily-doped area formed in the second N-type well.

15. The ESD protection device according to claim 12, further comprising a third N-type heavily-doped area formed in the first N-type well.

16. The ESD protection device according to claim 15, wherein the first N-type heavily-doped area, the first P-type heavily-doped area, and the third N-type heavily-doped area are coupled to a first pin and the N-type semiconductor substrate is coupled to a second pin.

17. The ESD protection device according to claim 16, wherein the first P-type heavily-doped area, the first N-type well, the P-type semiconductor layer, and the N-type semiconductor substrate form a parasitic silicon-controlled rectifier (SCR), the first N-type heavily-doped area, the P-type well, the P-type semiconductor layer, and the N-type semiconductor substrate form a parasitic vertical bipolar junction transistor (BJT), and when the first pin and the second pin respectively receive a positive electrostatic discharge (ESD) voltage and a grounding voltage, an electrostatic discharge (ESD) current flows from the first pin to the second pin through the parasitic SCR and the parasitic vertical BJT.

18. The ESD protection device according to claim 16, wherein the P-type well, the first N-type heavily-doped area, and the second N-type heavily-doped area form a parasitic lateral bipolar junction transistor (BJT), and when the first pin and the second pin respectively receive a negative electrostatic discharge (ESD) voltage and a grounding voltage, an electrostatic discharge (ESD) current flows from the second pin to the first pin through the N-type semiconductor substrate, the second N-type well, the external conductive wire, and the parasitic lateral BJT.

19. The ESD protection device according to claim 15, wherein the first N-type heavily-doped area, the first P-type heavily-doped area, and the third N-type heavily-doped area are coupled to a first pin and the external conductive wire is coupled to a second pin.

20. The ESD protection device according to claim 19, wherein the first P-type heavily-doped area, the first N-type well, the P-type semiconductor layer, the N-type semiconductor substrate, and the second N-type well form a parasitic silicon-controlled rectifier (SCR), the first N-type heavily-doped area, the P-type well, the P-type semiconductor layer, the N-type semiconductor substrate, and the second N-type well form a parasitic vertical bipolar junction transistor (BJT), and when the first pin and the second pin respectively receive a positive electrostatic discharge (ESD) voltage and a grounding voltage, an electrostatic discharge (ESD) current flows from the first pin to the second pin through the parasitic SCR and the parasitic vertical BJT.

21. The ESD protection device according to claim 19, wherein the P-type well, the first N-type heavily-doped area, and the second N-type heavily-doped area form a parasitic lateral bipolar junction transistor (BJT), and when the first pin and the second pin respectively receive a negative electrostatic discharge (ESD) voltage and a grounding voltage, an electrostatic discharge (ESD) current flows from the second pin to the first pin through the external conductive wire and the parasitic lateral BJT.

22. The ESD protection device according to claim 12, further comprising a second P-type heavily-doped area formed in the P-type well, and the second P-type heavily-doped area directly touches a bottom of the first N-type heavily-doped area.

23. The ESD protection device according to claim 22, further comprising a third P-type heavily-doped area formed in the P-type well, and the third P-type heavily-doped area directly touches a bottom of the second N-type heavily-doped area.
